(19) United States
(12) Patent Application Publication
(10) Pub. No.: US 2003/0071651 A1
(43) Pub. Date: Apr. 17, 2003

(54) Memory controlled signal steering and wave shaping circuit as a universal connector

(75) Inventor: Madhu Vora, Los Gatos, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Extensil, Inc., Sunnyvale, CA (US)

(21) Appl. No.: 10/238,930

(22) Filed: Sep. 9, 2002

Related U.S. Application Data
(60) Provisional application No. 60/322,254, filed on Sep. 13, 2001.

(51) Int. Cl. H03K 19/173

(52) U.S. Cl. 326/38

(57) ABSTRACT

A programmable connector, in accordance with the present invention, includes a pair of terminals that may be connected to or disconnected from each other via two separate paths. Each path includes a buffer and a switch whose control terminal receives a voltage supplied by a memory element associated with that path. If the voltages supplied by the memory elements respectively close and open the switches disposed in the first and second paths, a signal may only be transferred from the first terminal to the second terminal of the connector. If the voltages supplied by the memory elements respectively open and close the switches disposed in the first and second paths, a signal may only be transferred from the second terminal to the first terminal of the connector. If the voltages supplied by the memory elements open both switches, signal transfer between the first and second terminals of the connector is inhibited.

### CROSS-REFERENCES TO RELATED APPLICATIONS

The present application claims benefit of the filing date of U.S. provisional application No. 60/322,254, filed on Sep. 13, 2001, the entire content of which is incorporated herein by reference.

### BACKGROUND OF THE INVENTION

The present invention relates to Integrated Circuits (IC) containing programmable logic, and more particularly to a programmable interconnect structure for use in such ICs.

Advances in semiconductor fabrication processes which have enabled an ever increasing number of transistors to be formed on an IC fabricated on a single semiconductor substrate, have seen a parallel increase in the type and number of functions that such ICs may perform. One class of ICs, commonly referred to as programmable logic device (PLD), enables its users to program the functions that the PLD is required to perform. The various hardware blocks, commonly known as logic blocks, in a PLD are typically not connected to one another when the PLD is first supplied by its manufacturer. The user must First program the PLD to carry out the functions specified by the user. Programming of a PLD is usually performed with the aid of software in which the interconnections between various logic blocks are first specified, either by means of a table or a list of Boolean functions. After being executed, the software causes the specified interconnections to occur, in other words, it programs the PLD to create the desired logic and interconnections. A PLD thus eliminates the need for design-intensive and time-consuming efforts required for custom-specific ICs.

A PLD usually includes arrays of logic cells, known as logic blocks, that are programmable and are selectively connected to arrays of interconnect lines to attain both combinatorial as well as sequential logic functions. Programming of programmable logic blocks, as well as their connections to the selected lines (e.g., bus lines), is typically achieved by establishing the states of a multitude of programmable elements, such as memory cells or fuses, disposed in the PLD. The logic blocks disposed in a PLD often are divided into arrays of AND and OR functions, adapted to perform the specified functions.

One type of PLD is programmable array logic (PAL). In a PAL, the AND arrays are programmable, while the OR arrays are fixed. Accordingly, in a PAL, the AND gates are programmed to provide the product term logic signals which are subsequently summed by the OR gates.

Another type of PLD is known as programmable logic array (PLA) in which both the AND and OR arrays are programmable. In a PLA, the product terms in the AND array may be shared by the OR array to provide the specified logic functions. Both PALs and PLAs often include flip-flops, in addition to the AND and OR arrays, to provide sequential logic operations.

A disadvantage of both PALs and PLAs is their logic utilization. In other words, after being configured, some of the logic blocks disposed within a PLD may remain unutilized. To increase their utilization, PLDs have been adapted to include one or more macro cells. A macro cell is a logic block or a group of logic blocks that may be configured to perform many different and relatively more complex logic functions. A macro cell may be selectively interconnected to other macro cells or logic blocks. Macro cells enable attainment of a more granular structure and, therefore, increase the utilization of the semiconductor surface area in which the PLD is formed and, therefore, reduce cost.

Another type of IC which integrates a number of macro cells, analog and/or memory blocks on the same silicon substrate is commonly referred to as system-on-chip (SoC). An SoC may be configured to perform functions that would otherwise require several different ICs to perform.

The macro cells disposed in a conventional SoC are typically either hard wired during the fabrication process or are later programmed (i.e., configured) following the fabrication process. If hardwired during the fabrication process, an SoC may not be reconfigured following the completion of the fabrication process. If not configured during the fabrication process, an SoC is often configured with the aid of software. Such configuration software may be subsequently used to reconfigure the SoC to enable it to perform functions that are different from those for which the SoC was configured before. A reconfigurable SoC often employs arrays of interconnects which are selectively coupled to one another to provide the specified logic functions.

FIG. 2 of U.S. Pat. No. 5,504,440, issued to Sasaki, illustrates an interconnection between a logic cell 20 and input and output buses 23 and 17. Each line of bus 12 is shown as being coupled to an input terminal of logic cell 20 via “a programmable three state buffer operating under control of an input signal supplied to it on line 54. Line 54 is coupled to a register or other means within which the program for controlling the overall programmable logic device is stored.”

As disclosed in Sasaki, “A separate bit in this register, memory, a fuse or other means, is used to control a corresponding one of the programmable connections in the drawing in FIG. 2. Other bits are used to control other programmable connections elsewhere in the programmable logic device. Thus the control memory typically will have as many bits stored therein as there are programmable connections to be controlled. Of course, where two configurations are mutually exclusive and one, and only one, is always provided, the complementary state of a single bit can control two configurations. Under control of the memory bit, circuit 52a is either active or in a high impedance state. When the input 54a is enabled, circuit 52a repeats the signal coupled to its input node 57a. In other words, if a logical 1 is present on conductor 12a of bus 12, then input node 57a of driver 52a will be a logical 1. Assuming that control line 54a is enabled, then the output from driver 52a will also be a logical 1. Of course, the same conditions apply if a logical 0 is present on conductor 12a. Each of the drivers 52 functions in the same manner. On the other hand, if control line 54 is not enabled, then the driver circuits present a high impedance state and functionally behave as an open circuit. In other words, node 55 is completely disconnected from bus 12. This allows an input node 41 to be disconnected from the bus 12 when that input node is not to receive signals from bus 12.”

FIG. 9A of U.S. Pat. No. 4,870,302, issued to Freeman, is the schematic of a circuit for making a number of different interconnections. “Thus, in FIG. 9A, pass transistor 2, when activated into the conducting state, connects lead 90-3 to lead 90-1. Pass transistor 1, when conducting, connects lead 90-3 to lead 90-4. Pass transistor 4, when conducting, connects lead 90-4 to lead 90-2 and pass transistor 3, when conducting, connects lead 90-1 to lead 90-2. Pass transistors 6 and 5, when off, separate lead 90-2 from lead 90-3 and separate lead 90-1 from lead 90-4 respectively. Thus, should it be desired to connect vertical lead 90-2 to vertical lead 90-3, pass transistor 6 is activated. Likewise, should it be desired to connect horizontal lead 90-1 to horizontal lead 90-4, pass transistor 5 is activated.”

Conventional interconnect structures of the types that are deployed in known PLDs or SoCs may limit the reconfigurability of the macro cells disposed therein and may also limit the speed of operation. Such problems are further compounded as the supply voltages continue to scale down.

### BRIEF SUMMARY OF THE INVENTION

A programmable interconnect structure (hereinafter referred to as connector), in accordance with the present invention, includes a pair of terminals that may be connected to or disconnected from each other via two separate paths. Disposed in each path is a buffer and a switch whose control terminal is coupled to an output terminal of a programmable memory element associated with that path. If the voltages Supplied by the programmable memory elements associated with the first and second paths are respectively at first and second predefined values, the switches disposed in the first and second paths are respectively closed and open. Consequently, the first path is in a conducting state and the second path is in a non-conducting state, thereby enabling current to flow only from the first terminal to the second terminal of the connector. If the voltages supplied by the programmable memory elements associated with the first and second paths are respectively at the second and first predefined values, the switches disposed in the first and second paths are respectively open and closed. Consequently, the first path is in a non-conducting state and the second path is in a conducting state, thereby enabling current to flow only from the second terminal to the first terminal of the connector. If the voltages supplied by the programmable memory elements associated with the first and second paths both are at the second predefined value, both switches are open. Consequently, both the first and second paths are in non-conducting states, thereby inhibiting current flow between the first and second terminals of the connector.

The buffer in each of the first and second paths reduces the rise and fall times of the signal applied thereto, thereby restoring the signal's shape. The programmable memory elements are programmed during the programming phase, and depending on the values stored therein, either open or close the switches that they are coupled to.

In accordance with some embodiments of the present invention, each switch disposed in the connector may be an NMOS pass transistor or a PMOS pass transistor or a CMOS transmission gate. Each buffer may include one or more CMOS inverters. Each programmable memory element may be a fuse, a non-volatile memory, such as an Electrically Erasable Programmable Read Only Memory (EEPROM), a volatile memory, such a Static Random Access Memory (SRAM), or a register.

### BRIEF DESCRIPTION OF THE DRAWINGS

FIG. 1 illustrates a multitude of reconfigurable macro cells disposed within arrays of interconnect lines, in accordance with one embodiment of the present invention.

FIG. 2 is a symbol associated with the universal connector prior to being configured, in accordance with one embodiment of the present invention.

FIGS. 3A-3C are symbols associated with the universal connector of FIG. 2 after being configured.

FIG. 4 illustrates a bus having a multitude of interconnect lines each having sections which are adapted to be coupled to or uncoupled from one another via a multitude of universal connectors, in accordance with one embodiment of the present invention.

FIGS. 5A-5C illustrates the bus of FIG. 4 following three different configuration processes.

FIG. 6 illustrates a multitude of universal connectors disposed between a long bus and a short bus that, in turn, is coupled to a reconfigurable macro cell, in accordance with one embodiment of the present invention.

FIG. 7 is an expanded view of a portion of FIG. 6 illustrating the multitude of universal connectors disposed between the short and long buses, in accordance with one embodiment of the present invention.

FIG. 8 illustrates the conductive states of the multitude of the universal connectors of FIG. 7 following a configuration process, in accordance with one embodiment of the present invention.

FIG. 9 illustrates a multitude of universal connectors disposed between horizontal long bus lines and vertical long bus lines, in accordance with one embodiment of the present invention.

FIG. 10 is an expanded view of a portion of FIG. 9 illustrating the multitude of universal connectors disposed between the horizontal long bus lines and vertical long bus lines, following a configuration process, in accordance with one embodiment of the present invention.

FIG. 11 is a schematic block diagram of a universal connector, in accordance with one embodiment of the present invention.

FIG. 12 is a transistor schematic diagram of a programmable memory element disposed in the universal connector of FIG. 11, in accordance with one embodiment of the present invention.

FIG. 13 is a transistor schematic diagram of the universal connector of FIG. 11, in accordance with one embodiment of the present invention.

### DETAILED DESCRIPTION OF THE INVENTION

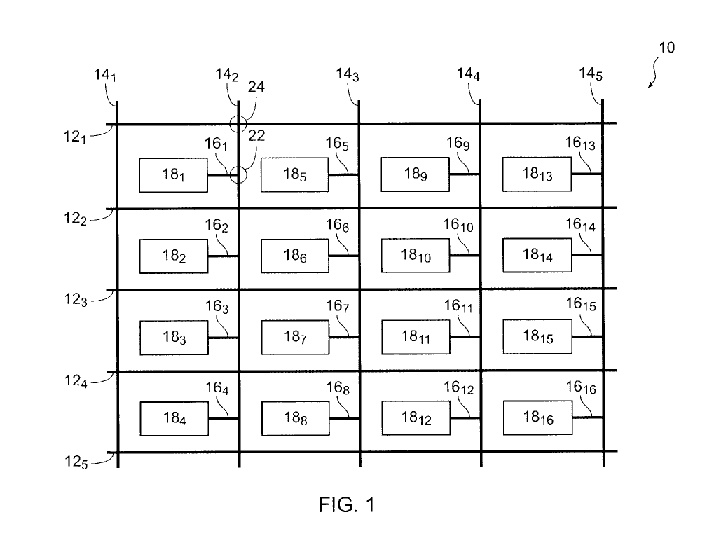

FIG. 1 is a simplified block diagram of a section of a programmable device 10, in accordance with one embodiment of the present invention. Programmable device 10 (hereinafter device 10) includes, among other components, a number of horizontal long routing channels 12, a number of vertical long routing channels 14, a number of horizontal short routing channels 16 and a number of reconfigurable macro cells 18 disposed within the arrays of long and short routing channels.

It is understood that each routing channel may be a bus having a multitude of electrically conductive lines. Accordingly, in the following, routing channels are alternatively referred to as buses. It is also understood that programmable device 10 may be a system-on-chip (SoC), a programmable logic device (PLD) or any other semiconductor integrated device adapted to be programmed (i.e., configured). Furthermore, although the following description is made with reference to reconfigurable macro cells 18, it is understood that the programmable interconnect structure, in accordance with the present invention, applies to any other programmable logic cell. In other words, the following description applies to all programmable cells, macro cells, logic blocks, or otherwise.

It is understood that each conductive line of horizontal long buses 12 and vertical long buses 14 includes more than one section, with adjacent sections of each line adapted to be connected to or disconnected from one another via a connector, in accordance with the present invention and as described further below. Short buses, on the other hand, include only one section.

In the following, different instances of similar components are alternatively identified by similar reference numerals having different indices—the indices appear as subscripts to the reference numerals. For example, the sixteen shown instances of programmable macro cells 18 are alternatively identified as 18₁, 18₂, 18₃ . . . 18₁₆. Similarly, for example, the five shown instances of horizontal short buses 12 are alternatively identified as 12₁, 12₂, 12₃ . . . 12₅.

Each reconfigurable macro cell 18 (alternatively referred to hereinbelow as programmable macro cell 1 8 or macro cell 18) is connected to a different one of short buses 16, which in turn, may be connected to or disconnected from one or more vertical long buses 14 and/or one or more horizontal long buses 12 via a group of universal connectors (not shown in FIG. 1). For example, macro cell 18₁ is connected to short horizontal bus 16₁ which, in turn, is connected to vertical long bus 14₂ at node 22 via a group of universal connectors (not shown). Vertical long bus 14₂, in turn, is connected to horizontal long bus 12₁ via another group of universal conductors (not shown) at node 24. Depending on the specified functions that device 10 is programmed to perform, different instances of macro cells 18 may be connected only to vertical long buses 14 or alternatively, may be connected to vertical long buses 14 as well as to horizontal long buses 12.

The disposition of macro cells 18 within the arrays of long and short buses, as shown in FIG. 1, enables signal transfers in accordance with any of the following conditions. First, a signal may be transferred from an output terminal of a macro cell 18 to a vertical long bus 14—via a short bus 16—from which it may be delivered to an output terminal of device 10. Second, a signal may be transferred from an input terminal of device 10 to an input terminal of a macro cell 18 via a vertical long bus 14 and a short bus 16. Third, a signal may transferred from an output terminal of a macro cell 18 to a vertical long bus 14—via a short bus 16—that, in turn, is coupled to a horizontal long bus 12 from which it is delivered to another short bus 16—via another vertical long bus 14—to an input port of another macro cell 18. Fourth, a signal may be transferred from any vertical long bus 14 to any horizontal long bus 12. Therefore, as shown in FIG. 1, signals may be transferred between any macro cells 18 and between any long and short buses. Each macro cell 18 of device 10 is typically configured to perform a number of logical operations in accordance with a list of Boolean functions or a logic table that is loaded into device 10 during configuration.

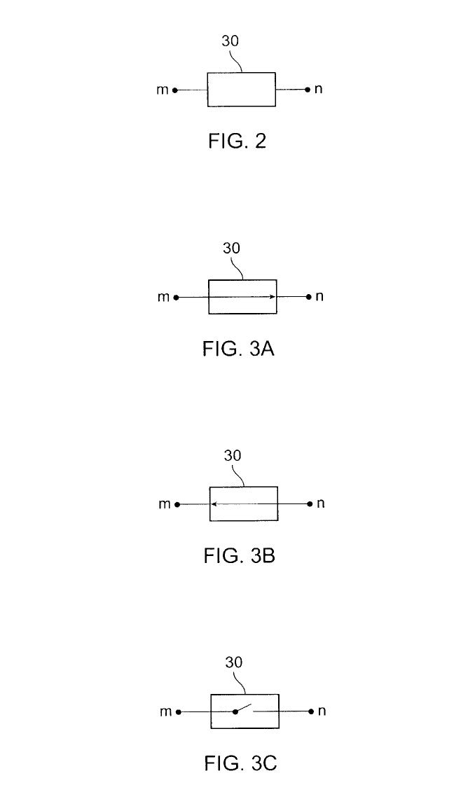

FIG. 2 is a symbol of a universal connector 30—prior to being configured—that is disposed between, for example, vertical long bus 14₂ and each of short horizontal bus 16₁ and long horizontal bus 12₁, respectively at nodes 22 and 24 (see FIG. 1). This is explained further below. Each universal connector 30 (alternatively referred to hereinbelow as connector 30) includes two terminals designated as m and n. Depending on the programming state of connector 30, current either (1) flows from terminal m to terminal n or, (2) from terminal n to terminal m or, (3) is inhibited from flowing between terminals m and n.

FIG. 3A is a symbol of connector 30 that is configured to conduct current from terminal m to terminal n. The direction of the current flow from terminal m to terminal n is also shown by the direction of the arrow. FIG. 3B is a symbol of connector 30 that is configured to conduct current from terminal n to terminal m; the direction of the current flow from terminal n to terminal m is also shown by the direction of the arrow. FIG. 3C is a symbol of connector 30 that is configured to inhibit current flow between terminals m and n. Accordingly, in FIG. 3C, terminals m and n are schematically shown as being connected to the terminals of an open switch.

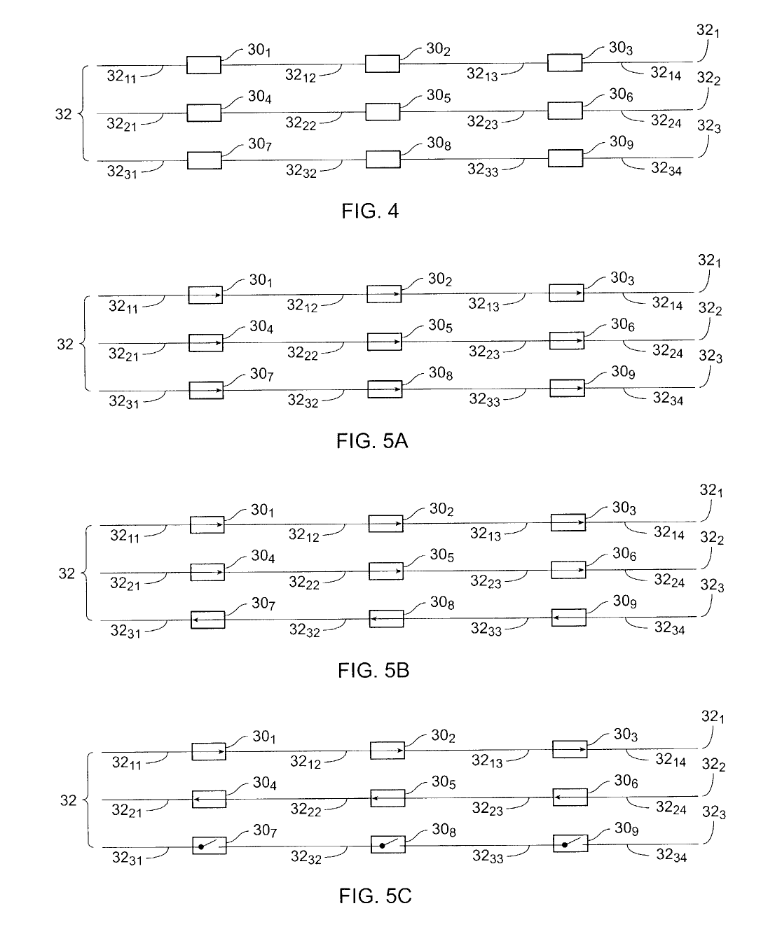

FIG. 4 illustrates a number of connectors 30 disposed between adjacent sections of bus 32. Bus 32 may be a vertical long bus or may be a horizontal long bus, as shown above. Bus 32 is shown as having three electrically conductive lines (hereinafter referred to as lines) but it will be appreciated that any number of lines may be used. Each line has as many sections as desired. In FIG. 4, four sections are shown. Each section, in turn, is connected to or disconnected from an adjacent section via a connector 30.

Each line of a bus is alternatively identified by a reference numeral which has an index appearing as a subscript thereto. The subscript refers to the line number (i.e., the bit position of the line within the bus) of the bus. Accordingly, in FIG. 4, the three lines of bus 32 are identified by reference numerals 32₁, 32₂ and 32₃. Furthermore, each bus line section is identified by a reference numeral having two-digit index appearing as a subscript thereto. The first digit of the index refers to the line number of the bus. The second digit of the index refers to the section number of the line identified by the first digit. Accordingly, for example, reference numeral 32₁₁ refers to the first section of the first line of bus 32 (i.e., bus line 32₁); reference numeral 32₁₂ refers to the second section of bus line 32₁; and reference numeral 32₁₄ refers to fourth section of bus line 32₁. Similarly, for example, reference numeral 32₃₁ refers to first section of the third line of bus 32 (i.e., bus line 32₃); reference numeral 32₃₂ refers to second section of bus line 32₃; and reference numeral 32₃₃ refers to third section of bus line 32₃.

Referring to FIG. 4, connectors 30₁, 30₂ . . . 30₉ connect or disconnect the various line sections of bus 32 between which they are disposed. For example, depending on its conduction state, connector 30₁ either connects bus section 32₁₁ to or disconnects bus section 32₁₁ from bus section 32₁₂. Similarly, depending on its conduction state, connector 30₅ either connects bus section 32₂₂ to or disconnects bus section 32₂₂ from bus section 32₂₃. Due to its inherent capacitance and resistance, each line of bus 32 may increase the propagation delay and distort the shape of the signal that it carries. To reduce the propagation delay and restore the signal's shape, a buffer is disposed in each switching path of each connector 30₁, 30₂ . . . 30₉. Each buffer amplifies the signal it receives by providing a voltage gain, thus reducing the propagation delay and restoring the shape of the signal that is carried over the bus line.

FIG. 5A illustrates an exemplary connectivity between various sections of bus 32 of FIG. 4, in accordance with a first configuration data. As seen from the conduction states of connectors 30, current flows from left to right on all three lines of bus 32. FIG. 5B illustrates another exemplary connectivity between various sections of bus 32 of FIG. 4, in accordance with a second configuration data. As seen from the conduction states of connectors 30, current flows from left to right on lines 32₁ and 32₂ and from right to left on line 32₃. FIG. 5C illustrates another exemplary connectivity between various sections of bus 32 of FIG. 4, in accordance with a third configuration data. As seen from the conduction states of connectors 30, current flows from left to right on lines 32₁ and from right to left on line 32₃. No current flows on line 32₃.

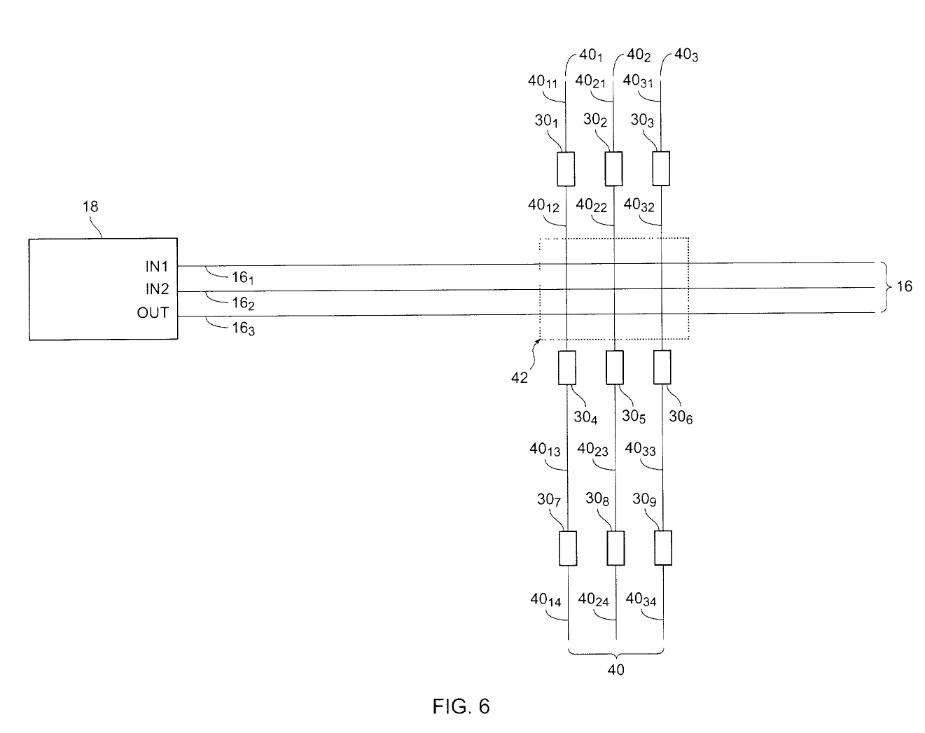

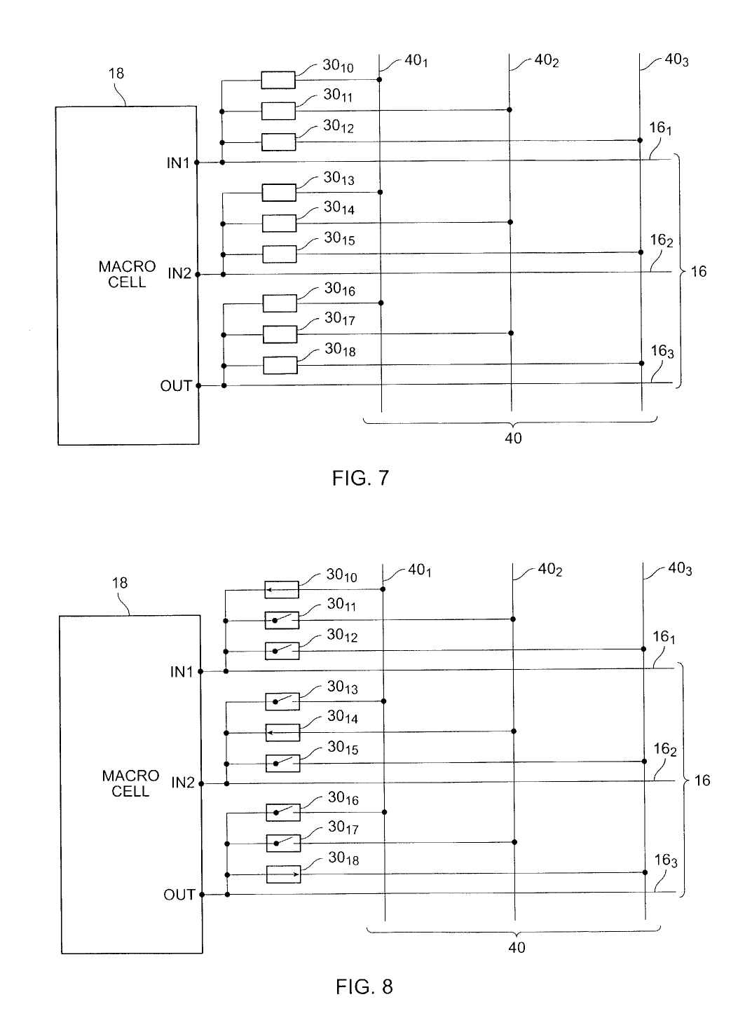

FIG. 6 illustrates a programmable macro cell 18 that is coupled to short bus 16 whose lines are, in turn, coupled to or uncoupled from the lines of long bus 40 via a number of connectors 30 (not shown in FIG. 6) disposed within the dotted perimeter line 42. More detailed description of the various connections inside the dotted perimeter line 42 is provided below in connection with FIG. 7. In the exemplary embodiment of FIG. 6, programmable macro cell 18 is shown as having two input terminals IN₁ and IN₂ that are coupled to short bus lines 16₁, 16₂, and one output terminal OUT coupled to bus line 16₃. It is understood, however, that in other embodiments macro cell 18 may have more or fewer input/output terminals, as is known by those skilled in the art. Moreover, in the exemplary embodiment of FIG. 6, the number of lines of bus 16 is the same as the number of input/output terminals of macro cell 18. However, it is understood that in other embodiments, the number of input/output terminals of macro cell 18 may be different from the number of lines of bus 16.

Referring to FIG. 6, long bus 40 includes 3 lines, each of which is shown as having four sections. Each section of each line of bus 40 is coupled to or uncoupled from an adjacent section of the same bus line via a connector 30. For example, sections 40₂₃ and 40₂₄ may be coupled to or uncoupled from one another by so configuring connector 30₈. Therefore, connectors 30, in accordance with the present invention, may be configured to establish connectivity between (1) adjacent sections of the same bus line, (2) different lines of different buses and (3) input/output terminals of a macro cell and a bus.

FIG. 7 illustrates the multitude of connectors 30 disposed between the lines of buses 16 and 40, as described above in connection with dotted perimeter line 42 of FIG. 6, before device 10 is programmed. As seen from FIG. 7, a connector 30 is disposed between each line of bus 16 and each line of bus 40. For example, connector 30₁₀ is disposed between bus lines 16₁ and 40₁; connector 30₁₁ is disposed between bus lines 16₁ and 40₂, and connector 30₁₂ is disposed between bus lines 16₁ and 40₃. Similarly, connector 30₁₆ is disposed between bus lines 16₃ and 40₁; connector 30₁₇ is disposed between bus lines 16₃ and 40₂; and connector 30₁₈ is disposed between bus lines 16₁ and 40₃. Therefore, by configuring the nine shown connectors 30 of FIG. 7, each terminal of macro cell 18 may be coupled to or uncoupled from a different one of the lines of bus 40. Furthermore, the direction of the current flow between the two terminals of each connector 30 is so selected as to enable signals to be delivered to input terminals IN₁ and IN₂ and to be received from output terminal OUT of macro cell 18. The signals delivered to input terminals IN₁ and IN₂ as well as the signal received from output terminal OUT are carried by the lines of bus 40 when so configured. Each connector 30 of FIG. 7 is selectively and individually configurable, in accordance with the present invention, to provide a specific connectivity between the lines of bus 40 and input/output terminals of macro cell 18 via the lines of bus 16, as described further below.

FIG. 8 illustrates the connectivity established between the terminals of macro cell 18 and the lines of bus 40 of FIGS. 6 and 7 following an exemplary configuration operation. In accordance with the data loaded into device 10 during such a configuration operation, connector 30₁₀ is so configured as to enable current to flow from line 40₁ to input terminal IN₁ of macro cell 18. To inhibit current flow between input terminal IN₁ and lines 40₂ and 40₃, connectors 30₁₁ and 30₁₂ are placed in non-conducting states. Similarly, connector 30₁₄ is so configured as to enable current to flow from line 40₂ to input terminal IN₂ of macro cell 18. To inhibit current flow between input terminal IN₂ and lines 40₁ and 40₃, connectors 30₁₃ and 30₁₅ are placed in non-conducting states. Connector 30₁₈ is so configured as to enable current to flow from output terminal OUT of macro cell 18 to line 40₃. To inhibit current flow between output terminal OUT and lines 40₁ and 40₂, connectors 30₁₆ and 30₁₇ are placed in non-conducting states.

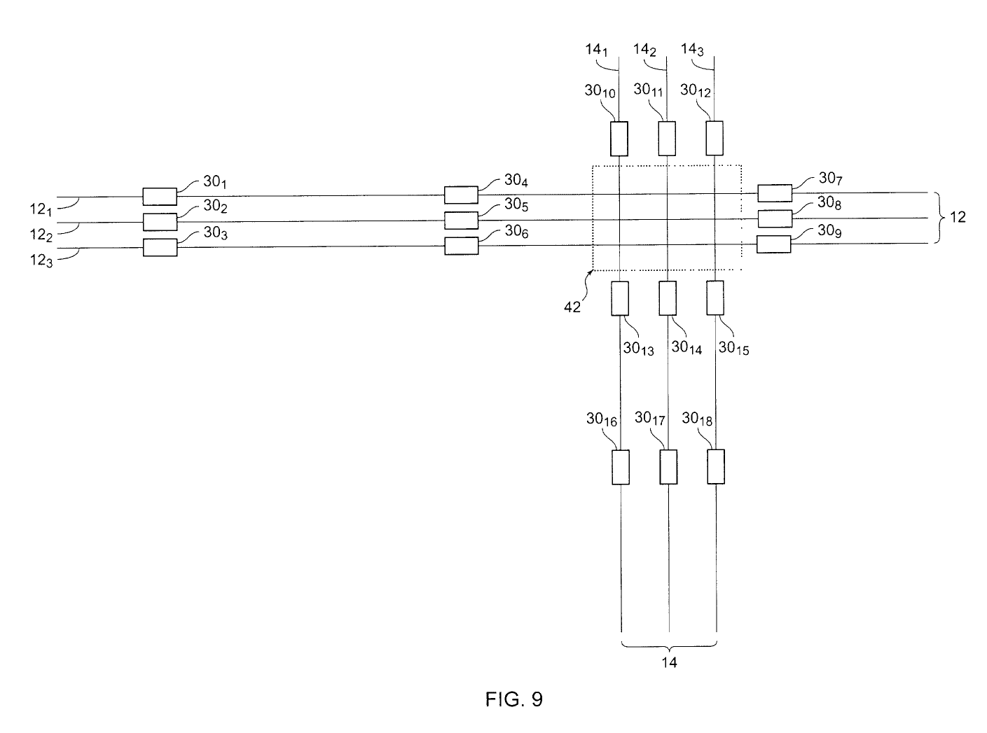

FIG. 9 illustrates horizontal long bus 12 whose lines are coupled to or uncoupled from the lines of vertical long bus 14 via a number of connectors 30 (not shown in FIG. 9) disposed within the dotted perimeter line 44. Horizontal long bus 12 has three lines 12₁, 12₂ and 12₃ each of which is shown to have four sections. A connector 30 is disposed between adjacent sections of each line of bus 12. Similarly, vertical long bus 14 has three lines 14₁, 14₂ and 14₃ each of which is shown to have four sections. A connector 30 is disposed between adjacent sections of each line of bus 14. Each connector 30 of FIG. 9 is selectively and individually configurable, in accordance with the present invention, to provide a specific connectivity between the lines of buses 12 and 14, as described further below.

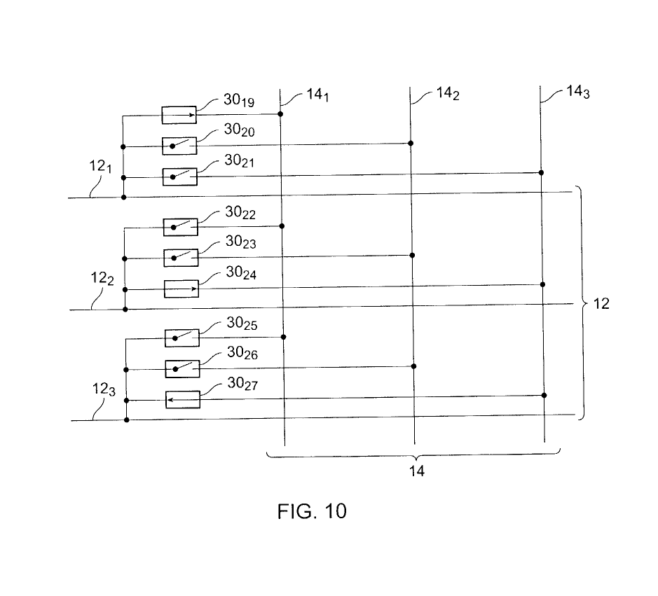

FIG. 10 illustrates the multitude of connectors 30 disposed between the lines of buses 12 and 14, as described above in connection with dashed perimeter line 44 of FIG. 9, following an exemplary configuration operation. In accordance with the data loaded into device 10 during the configuration operation, connector 30₁₉ is configured so as to enable current to flow from line 12₁ to line 14₁. To inhibit current flow between line 12₁ and each of lines 14₂ and 14₃, connectors 30₂₀ and 30₂₁ are placed in non-conducting states. Connector 30₂₄ is configured so as to enable current to flow from line 12₂ to line 14₃. To inhibit current flow between line 12₂ and each of lines 14₁ and 14₂, connectors 30₂₂ and 30₂₃ are placed in non-conducting states. Connector 30₂₇ is configured so as to enable current to flow from line 14₃ to line 12₃. To inhibit current flow between line 12₃ and each of lines 14₁ and 14₂, connectors 30₂₅ and 30₂₆ are placed in non-conducting states.

As seen from FIG. 10 and from the description above, line 14₂ is not coupled to any of lines 12₁, 12₂ and 12₃. Moreover, since lines 12₂ and 12₃ are coupled to one another via line 14₃, some or all of the current on line 12₂ flows to line 12₃ via line 14₂. Therefore, for instance, by coupling bus lines 12₂ and 12₃ respectively to output and input terminals of a macro cell, the signal generated at the output terminal of the macro cell may be delivered to the input terminal of the same macro cell.

FIG. 11 is a simplified block diagram of a connector 30, in accordance with one embodiment of the present invention. Connector 30 includes inverters 56, 58, switches 52, 54, and memory elements 60 and 62. Terminals A and B of switch 54 are respectively coupled to terminal n of connector 30 and to output terminal OUT of inverter 58. Control terminal C of switch 54 is coupled to output terminal Q of memory element 60. Terminals A and B of switch 52 are respectively coupled to terminal m of connector 30 and to output terminal OUT of inverter 56. Control terminal C of switch 52 is coupled to output terminal Q of memory element 62. Input terminals IN of inverters 58 and 56 are respectively coupled to terminals m and n of connector 30.

Switches 52 and 54 each conducts current between its terminals A and B (i.e., the switch is closed) when the voltage applied to the switch's control terminal C is at a predefined value. If, for example, each switch 52, 54 is an NMOS pass gate transistor, the switch is closed when the voltage applied to the switch's control terminal (i.e., gate terminal) C is at a high level, as known to those skilled in the art. If, for example, each switch 52, 54 is a PMOS pass gate transistor, the switch is closed when the voltage applied to the control terminal C of the switch is at a low level, as known to those skilled in the art. In the following, it is assumed that each switch 52, 54, conducts current when the voltage applied to the switch's control terminal C is at a high level.

Memory elements 60 and 62 are programmed either (1) to enable current to flow from terminal m to terminal n via programmable path 96 (hereinafter referred to as path 96) defined by inverter 58 and switch 54, or (2) to enable current to flow from terminal n to terminal m via programmable path 98 (hereinafter referred to as path 98) defined by inverter 56 and switch 52, or (3) to inhibit current flow between terminals m and n, as described further below.

In accordance with the first programming state, memory element 60 is programmed to generate a high voltage at its output terminal Q, and memory element 62 is programmed to generate a low voltage at its output terminals Q. Accordingly, switch 54 is closed and switch 54 is open. Since switch 54 is closed, path 96 is in a conducting state, thus enabling current to flow from terminal m to terminal n. Since switch 52 is open, path 98 is in a non-conducting state, therefore, no current flows from terminal n to terminal m. The signal generated at output terminal OUT of inverter 58 is the inverse of the signal that inverter 58 receives at its input terminal IN. Therefore, signals present at terminals m and n of the connector are inverse of each other.

In accordance with the second programming state, memory elements 60 and 62 are respectively programmed to generate low and high voltages at their respective output terminals Q. Accordingly, switch 52 is closed and switch 54 is open. Since switch 52 is closed, path 98 is in a conducting state, thus enabling current to flow from terminal n to terminal m. Since switch 54 is open, path 96 is in a non-conducting state, therefore, no current flows from terminal m to terminal n. The signal generated at output terminal OUT of inverter 56 is the inverse of the signal that inverter 56 receives at its input terminal IN. Therefore, signals present at terminals n and m of the connector are inverse of each other.

In accordance with the third programming state, memory elements 60 and 62 both are programmed to generate low voltages at their respective output terminals Q. Accordingly, switches 52 and 54 both are open, thus causing paths 96 and 98 both to be in non-conducting states, thereby inhibiting current flow between terminals n and m. Consequently, in accordance with the present invention and depending on the voltages applied, connector 30 either steers signals from left to right (i.e., from terminal m to terminal n), or from right to left, or inhibits the flow of signals.

Memory elements 60 and 62 each has three input terminals that control the voltage levels of their output terminals Q. Accordingly, both the establishment of a conduction path between terminals (alternatively referred to as nodes) m and n, as well as the direction of the current flow between nodes m and n—when a conduction path is established—is controlled by the voltages applied to input terminals of memory elements 60 and 62 during the configuration process.

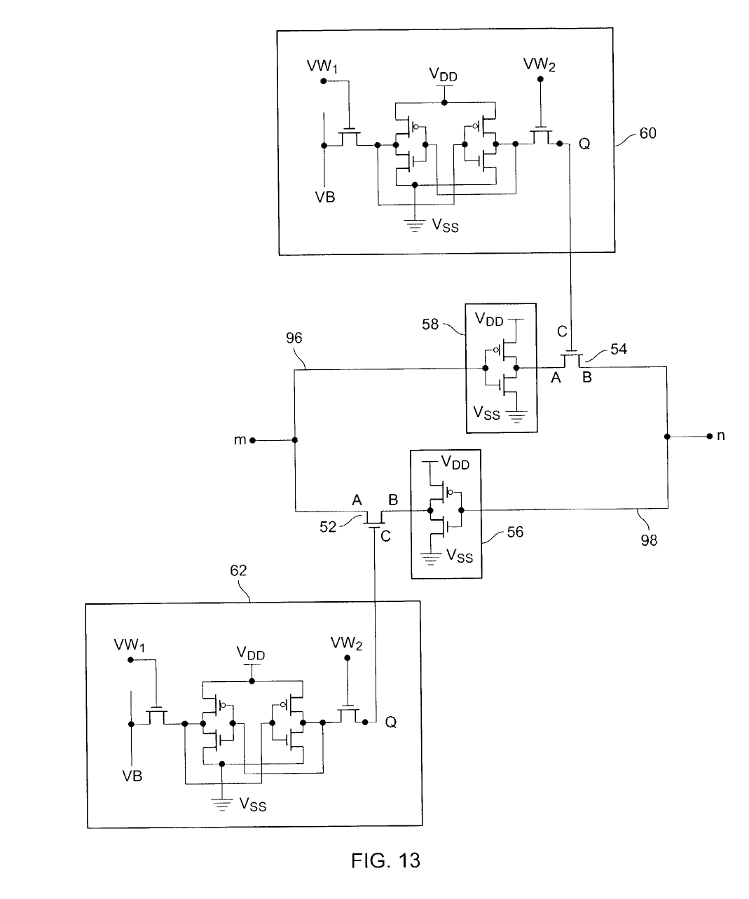

In some embodiments, inverters 56 and 58 are each CMOS inverters having an NMOS and a PMOS transistor, as is known in the art (see FIG. 13). Each inverter 56, 58 is a buffer and each provides a voltage gain that reduces the rise and fall times of the signal the inverter receives, thereby to restore the signal's shape, as described further below.

Internally generated signals, such as those generated by a macro cell 18, typically have rapid transitions, in other words, they have fast rise and fall times. However, the rise and fall times associated with such signals increase as the signals are carried from one location to another location over a bus—such as any of the buses shown and described above. The longer the bus, the higher are its resistance and capacitance and thus the longer are the rise and fall times of any signal that the bus carries. The increases in signal rise and fall times, in turn, increase the time period that it takes for the signal to arrive at its destination, thereby lowering the operation speed and the performance. To improve performance by reducing the travel time of a signal from its source (e.g., a macro cell) to its destination (e.g., another macro cell) when the signal is carried over a long bus, inverters 56 and 58 each provides a voltage gain that reduces the rise and fall times of the signal that is applied to the inverter In other words, inverters 56 and 58 of connector 30 each, in addition to being an inverting circuit, is also a wave shaping circuit.

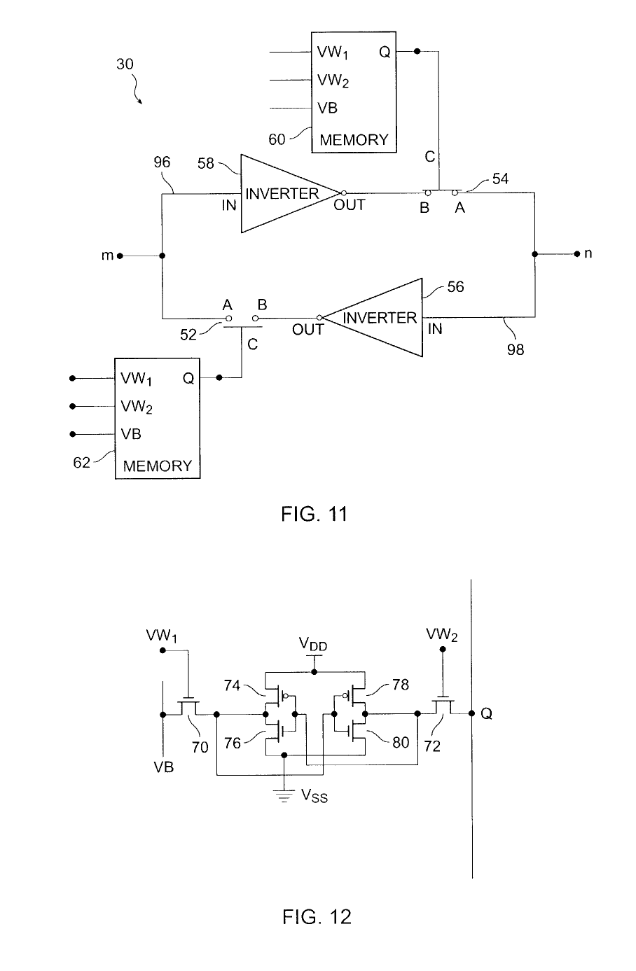

FIG. 12 is a transistor schematic diagram of each of memory elements 60 and 62, in accordance with one embodiment of the present invention. The gate and drain terminals of NMOS transistor 70 are respectively coupled to input terminals VW₁ and VB of the memory element. The source terminal of transistor 70 is coupled to the drain terminals of PMOS transistor 74 and NMOS transistor 76, to gate terminals of NMOS transistor 80 and PMOS transistor 78, as well as to the drain terminal of NMOS transistor 72. The source terminals of PMOS transistor 74 and NMOS transistors 76 are respectively coupled to first voltage supply V_{dd} and to the ground terminal. The gate terminals of PMOS transistor 74 and NMOS transistors 76 are coupled to the drain terminals of NMOS transistor 80 and PMOS transistors 78, as well as to the drain terminal of NMOS transistor 72. The source terminals of PMOS transistor 78 and NMOS transistors 80 are respectively coupled to the first voltage supply V_{dd} and to the ground terminal. The gate terminal of NMOS transistor 72 is coupled to input terminal VW₂ of the memory element. The source terminal of NMOS transistor 72 is coupled to output terminal Q of the memory element. The operation of the memory element of FIG. 12 is described below.

To generate a high voltage on output terminal Q, a high voltage is applied to input terminal VW₁ and a low voltage is applied to input terminal VB during a configuration process. The low voltage applied to terminal VB is transferred to the gate terminals of PMOS transistor 78 and NMOS transistor 80—via transistor 70—causing NMOS transistor 80 to turn off and PMOS transistor 78 to turn on. Therefore, the voltage at the drain terminals of transistors 78 and 80 is pulled up to the supply voltage V_{dd}. The high voltage present at the drain terminals of transistors 78 and 80 causes NMOS transistor 76 to turn on and PMOS transistor 74 to turn off which, in turn, causes the voltage at the drain terminals of transistor 74 and 76 to go low. Therefore, the low voltage applied to input terminal VB is latched, thereby causing the voltage present at the drain terminals of transistors 78, 80 and 72 to be maintained at a high level. During the configuration process, the voltage applied to input terminal VW₂ is maintained at a low level to keep transistor 72 off, thus isolating the drain terminals of transistors 78, 80, 72 from output terminal Q. After the configuration process is terminated, the voltage applied to input terminal VW₂ is raised to a high level to pass the high voltage present at the drain terminals of transistors 72, 78 and 80 to output terminal Q.

To generate a low voltage on output terminal Q and a high voltage on output terminal QB, high voltages are applied to input terminals VW₁ and VB, during a configuration process. The high voltage applied to terminal VB is transferred to the gate terminals of PMOS transistor 78 and NMOS transistor 80—via transistor 70—causing NMOS transistor 80 to turn on and PMOS transistor 78 to turn off. Therefore, the voltage at the drain terminals of transistors 78 and 80 is pulled to the ground potential. The low voltage present at the drain terminals of transistors 78 and 80 causes NMOS transistor 76 to turn off and PMOS transistor 74 to turn on which, in turn, causes the voltage at the drain terminals of transistor 74 and 76 to go high. Therefore, the high voltage applied to input terminal VB is latched. After the configuration process is terminated, the voltage applied to input terminal VW₂ is raised to a high level to pass the low voltage from the drain terminals of transistors 72, 78 and 80 to output terminal Q.

FIG. 13 is a transistor schematic diagram of a connector 30, in accordance with the embodiments described above. In accordance with FIG. 13, switches 54 and 52 are each NMOS pass transistors. The gate terminals of NMOS transistors 54 and 52 are respectively coupled to output terminals Q of memory elements 60 and 62. Inverters 58 and 56 each is a CMOS inverter which includes a PMOS and a NMOS transistor, as is known in the art.

To pass a signal from terminal m to terminal n, memory elements 60 and 62 are respectively configured to generate high and low voltages at their respective terminals Q. As a result of such configuration, NMOS transistor 54 is on while NMOS transistor 52 is off. Therefore, path 96 is in a conducting state, thus enabling signal transfer from terminal m to terminal n. Since NMOS transistor 52 is off, path 98 is in a non-conducting state thus preventing signal transfer from terminal m to terminal n. The signal present at terminal n is the inverse of the signal at terminal m. To ensure that the signal at terminal n is not inverted, a second inverter may be disposed in path 96 and in series with inverter 58, as is known to those skilled in the art.

To pass a signal from terminal n to terminal m, memory elements 60 and 62 are respectively configured to generate low and high voltages at their respective terminals Q. As a result of such configuration, NMOS transistor 52 is on while NMOS transistor 54 is off. Therefore, path 98 is in a conducting state, thus enabling signal transfer from terminal n to terminal m. Since NMOS transistor 54 is off, path 96 is non-conducting state thus preventing signal transfer from terminal n to terminal m. The signal present at terminal m is the inverse of the signal at terminal n. To ensure that the signal at terminal m is not inverted, a second inverter may be disposed in path 98 and in series with inverter 56.

To inhibit signal transfer between terminals m and n, memory elements 60 and 62 both are configured to generate low voltages at their respective terminals Q. As a result of such configuration, NMOS transistors 52 and 54 both are off. Therefore, both paths 96 and 98 are in non-conducting states, thus inhibiting signal transfer between terminals m and n.

The above embodiments of the present invention are illustrative and not limitative. The invention is not limited by the type of switch, inverter or memory element that is disposed in the universal connector, in accordance with the present invention. Nor is the invention limited by the type of the technology, CMOS, Bipolar, BICMOS or otherwise that may be used to from the universal connector. The invention is not limited by the type of integrated circuit in which the universal connector is disposed. For example, the universal connector, in accordance with the present invention, may be disposed in a programmable logic device, a SoC or any other IC which is adapted to be configured. Nor is the invention limited by the type of logic cell, macro cell or otherwise, that may be configured using the universal connector of the present invention. Other additions, subtractions or modification are obvious in view of the present invention and are intended to fall within the scope of the appended claims.

What is claimed is:

1. A programmable connector comprising:
a first and a second terminal;
a first buffer having an input terminal coupled to the first terminal of the programmable connector and an output terminal coupled to a first terminal of a first switch, wherein a second terminal of the first switch is coupled to the second terminal of the programmable connector and wherein a control terminal of the first switch is adapted to receive a first voltage; the first buffer and the first switch defining a first path between the first and second terminals of the programmable connector; and
a second buffer having an input terminal coupled to the second terminal of the programmable connector and an output terminal coupled to a first terminal of a second switch, wherein a second terminal of the second switch is coupled to the first terminal of the programmable connector and wherein a control terminal of the second switch is adapted to receive a second voltage; the second buffer and the second switch defining a second path between the first and second terminals of the programmable connector; wherein the first and second paths are respectively in conducting and non-conducting states if the first and second voltages are respectively at first and second predefined values, wherein the first and second paths are respectively in non-conducting and conducting states if the first and second voltages are respectively at the second and first predefined values, and wherein the first and second paths both are in non-conducting states if the first and second voltages both are at the second predefined value.

2. The programmable connector of claim 1 wherein each of the first and second buffers includes at least one CMOS inverter.

3. The programmable connector of claim 1 wherein each of the first and second switches is selected from a group consisting of NMOS pass transistor, PMOS pass transistor and CMOS transmission gate.

4. The programmable connector of claim 3 wherein the first and second voltages are respectively generated by first and second programmable memory elements.

5. The programmable connector of claim 4 wherein each of the first and second programmable memory elements is selected from a group consisting of register, fuse, volatile memory and non-volatile memory.

6. The programmable connector of claim 5 wherein each of the first and second programmable memory elements comprises:
a first transistor having a gate terminal that receives a first voltage, a source terminal that is coupled to the control terminal of the programmable switch associated with the memory element and a drain terminal;
second and third transistors whose drain terminals are coupled to the drain terminal of the first transistor, wherein the gate terminals of the second and third transistors are coupled to one another, wherein the second and third transistors respectively receive first and second supply voltages at their source terminals;
fourth and fifth transistors whose gate terminals are coupled to the drain terminals of the second and third transistors, source terminals that are coupled to the gate terminals of the second and third transistors, wherein the third and fourth transistors respectively receive the first and second supply voltages at their source terminals;
a fifth transistor having a source terminal that is coupled to the drain terminals of the fourth and fifth transistors, a gate terminal that receives a second voltage and a drain terminal that receives a third voltage.

7. The programmable connector of claim 6 wherein the first, third, fifth and sixth transistors in each of the memory elements are NMOS transistors and wherein the second and the fourth transistors in each of the memory elements are PMOS transistors.

8. A method for controlling signal transfer between first and second nodes, the method comprising:
transferring the signal from the first node to the second node via a first path in which a first switch is disposed and inhibiting the signal transfer from the second node to the first node via a second path in which a second switch is disposed if first and second programmable voltages applied respectively to the first and second switches are respectively at first and second predefined values;
transferring the signal from the second node to the first node via the second path and inhibiting the signal transfer from the first node to the second node via the first path if the first and second programmable voltages are respectively at the second and first predefined values; and
inhibiting the signal transfer between the first and second nodes via both the first and second paths if the first and second programmable voltages both are at the second predefined value.

9. The method of claim 8 further comprising:
buffering the signal transferred via the first path.

10. The method of claim 9 further comprising:
buffering the signal transferred via the second path.

11. The method of claim 10 wherein each of the first and second switches is selected from a group consisting of NMOS pass transistor, PMOS pass transistor and CMOS transmission gate.

12. The method of claim 11 wherein the first and second programmable voltages are respectively supplied by first and second programmable memory elements.

13. The method of claim 12 wherein each of the first and second programmable memory elements comprises:
a first transistor having a gate terminal that receives a first voltage, a source terminal that is coupled to a control terminal of one of the first and switches and a drain terminal;
second and third transistors whose drain terminals are coupled to the drain terminal of the first transistor, wherein the gate terminals of the second and third transistors are coupled to one another, wherein the second and third transistors respectively receive first and second supply voltages at their source terminals;
fourth and fifth transistors whose gate terminals are coupled to the drain terminals of the second and third transistors, source terminals that are coupled to the gate terminals of the second and third transistors, wherein the third and fourth transistors respectively receive the first and second supply voltages at their source terminals; and
a fifth transistor having a source terminal that is coupled to the drain terminals of the fourth and fifth transistors, a gate terminal that receives a second voltage and a drain terminal that receives a third voltage.

14. A programmable gate array comprising:
a horizontal bus having a plurality of lines;
a vertical bus having a plurality of lines; and
a plurality of programmable connectors disposed between the plurality of lines of the horizontal bus and the plurality of lines of the vertical bus, each programmable connector further comprising:
a first and a second terminal;
a first buffer having an input terminal coupled to the first terminal of the programmable connector and an output terminal coupled to a first terminal of a first switch, wherein a second terminal of the first switch is coupled to the second terminal of the programmable connector and wherein a control terminal of the first switch is adapted to receive a first voltage; the first buffer and the first switch defining a first path between the first and second terminals of the programmable connector; and
a second buffer having an input terminal coupled to the second terminal of the programmable connector and an output terminal coupled to a first terminal of a second switch, wherein a second terminal of the second switch is coupled to the first terminal of the programmable connector and wherein a control terminal of the second switch is adapted to receive a second voltage; the second buffer and the second switch defining a second path between the first and second terminals of the programmable connector; wherein the first and second paths are respectively in conducting and non-conducting states if the first and second voltages are respectively at first and second predefined values, wherein the first and second paths are respectively in non-conducting and conducting states if the first and second voltages are respectively at the second and first predefined values, and wherein the first and second paths both are in non-conducting states if the first and second voltages both are at the second predefined value.

15. The programmable gate array of claim 14 wherein each line of the horizontal and vertical buses has a plurality of sections and wherein a programmable connector is disposed between each section of each line of the horizontal bus and an associated section of the vertical bus line.

16. The programmable gate array of claim 14 wherein each of the first and second buffers includes at least one CMOS inverter.

17. The programmable gate array of claim 14 wherein each of the first and second switches is selected from a group consisting of NMOS pass transistor, PMOS pass transistor and CMOS transmission gate.

18. The programmable gate array of claim 17 wherein the first and second voltages are respectively generated by first and second programmable memory elements.

19. The programmable gate array of claim 18 wherein each of the first and second programmable memory elements is selected from a group consisting of register, fuse, volatile memory and non-volatile memory.

20. The programmable gate array of claim 19 wherein each of the first and second programmable memory elements comprises:
a first transistor having a gate terminal that receives a first voltage, a source terminal that is coupled to the control terminal of the programmable switch associated with the memory element and a drain terminal;
second and third transistors whose drain terminals are coupled to the drain terminal of the first transistor, wherein the gate terminals of the second and third transistors are coupled to one another, wherein the second and third transistors respectively receive first and second supply voltages at their source terminals;
fourth and fifth transistors whose gate terminals are coupled to the drain terminals of the second and third transistors, source terminals that are coupled to the gate terminals of the second and third transistors, wherein the third and fourth transistors respectively receive the first and second supply voltages at their source terminals;
a fifth transistor having a source terminal that is coupled to the drain terminals of the fourth and fifth transistors, a gate terminal that receives a second voltage and a drain terminal that receives a third voltage.

21. The programmable gate array of claim 20 wherein the first, third, fifth and sixth transistors in each of the memory elements are NMOS transistors and wherein the second and the fourth transistors in each of the memory elements are PMOS transistors.

22. A method comprising:
transferring a signal from a first node to a second node via a first path in which a first switch is disposed and inhibiting the signal transfer from the second node to the first node via a second path in which a second switch is disposed if First and second programmable voltages applied respectively to the first and second switches are respectively at first and second predefined values;
transferring the signal from the second node to the first node via the second path and inhibiting the signal transfer from the first node to the second node via the first path if the first and second programmable voltages are respectively at the second and first predefined values; and
inhibiting the signal transfer between the first and second nodes via both the first and second paths if the first and second programmable voltages both are at the second predefined value, wherein said first node represents a node of a horizontal bus disposed in a programmable gate array and wherein said second node represents a node of a vertical bus disposed in the programmable gate array.
